(19) United States
(12) Patent Application Publication
(10) Pub. No.: US 2008/0266807 A1
(43) Pub. Date: Oct. 30, 2008

(54) ELECTRONIC ASSEMBLY WITH EMI SHIELDING HEAT SINK

(75) Inventors: Eric D. Lakin, Chippewa Falls, WI (US); Paul Bonstrom, Eau Claire, WI (US)

Correspondence Address: SCHWEGMAN, LUNDBERG & WOESSNER, P.A., P.O. BOX 2938, MINNEAPOLIS, MN, 55402, US

(73) Assignee: Cray Inc., Seattle, WA (US)

(21) Appl. No.: 11/741,566

(22) Filed: Apr. 27, 2007

(51) Int. Cl. H05K 7/20

(52) U.S. Cl. 361/709; 361/719

(57) ABSTRACT

An example electronic assembly includes a substrate that has a first surface and a second surface. The first surface of the substrate includes a grounding ring. The electronic assembly further includes one or more electronic components that are mounted on the first surface of the substrate such that the grounding ring at least partially surrounds the electronic components(s). A heat sink engages the electronic component(s) and the grounding ring in order provide cooling and EMI shielding to the electronic components(s). In some embodiments, the grounding ring surrounds the entire electronic components(s) and the heat sink engages the entire grounding ring, although in other embodiments, the grounding ring may partially surround the electronic components(s) and/or the heat sink may engage just a portion of the grounding ring.

### FEDERALLY SPONSORED RESEARCH OF DEVELOPMENT

The U.S. Government has a paid-up license in this invention and the right in limited circumstances to require the patent owner to license others on reasonable terms as provided for by the terms of Contact No. MDA904-02-3-0052, awarded by the Maryland Procurement Office.

### BACKGROUND OF THE INVENTION

1. Field of the Invention

The present invention is related to an electronic assembly, and more particularly to an electronic assembly that includes a heat sink which provides electromagnetic interference (hereafter EMI) shielding.

2. Background Information

Electronic devices generate heat during operation. Thermal management refers to the ability to keep temperature-sensitive elements in an electronic device within a prescribed operating temperature.

Historically, electronic devices have been cooled by natural convection. The cases or packaging of the devices included strategically located openings (e.g., slots) that allowed warm air to escape and cooler air to be drawn in.

The advent of high performance electronic devices now requires more innovative thermal management. Each increase in processing speed and power generally carries a “cost” of increased heat generation such that natural convection is no longer sufficient to provide proper thermal management. If the heat generated by such electronic devices is not removed at a sufficient rate, the devices may overheat resulting in damage to the devices and/or a reduction in operating performance of the devices.

One common method of cooling an electronic device includes thermally coupling a heat sink to an electronic device. A typical heat sink includes protrusions (e.g., fins or pins) which project from a body of the heat sink. The protrusions give the heat sink a larger surface area such that the heat sink dissipates a greater amount of thermal energy from the electronic device into the surrounding environment. Heat sinks are fabricated from materials with high thermal conductivity in order to efficiently transfer thermal energy from the electronic device to the ambient environment.

A fan is often used in conjunction with the heat sink to improve the heat sink's rate of cooling. The fan causes air to move past the fins on the heat sink. Moving air past the heat sink increases the rate of convection between the heat sink and the ambient environment where the heat sink is located. Increasing the rate of convection between the heat sink and the ambient environment reduces the temperature of the heat sink, thereby enhancing the heat sink's ability to transfer heat from the electronic device.

The ability to thermally manage electronic devices becomes even more difficult when multiple electronic components are mounted in close proximity to one another within an electronic system. As an example, multiple chipsets, dies, processors, memory modules and/or application specific integrated circuits (hereafter asics) may be mounted in close proximity to one another such that the heat generated by each electronic component can adversely effect the performance that particular component as well as the other electronic components.

Electronic devices also generate EMI during operation with high performance electronic components generally producing relatively large amounts of EMI. The EMI that is generated by such electronic components may be large enough to reduce the operating performance of the electronic components which are included in an electronic system.

The heat sinks in existing electronic assemblies are typically used to cool high performance electronic components when multiple electronic components are mounted in close proximity to one another within an electronic device. Therefore, what is needed is an electronic assembly which includes a heat sink that provides high performance cooling and EMI shielding to an electronic component when electronic components are mounted in close proximity to one another within an electronic system.

### BRIEF DESCRIPTION OF THE DRAWINGS

FIG. 1 illustrates an exploded perspective view of an example electronic assembly.

FIG. 2 illustrates a schematic surface view of the electronic assembly shown in FIG. 1.

FIG. 3 illustrates an exploded perspective view of another example electronic assembly.

FIG. 4 illustrates a schematic surface view of the electronic assembly shown in FIG. 3.

FIG. 5 illustrates an exploded perspective view of another example electronic assembly.

FIG. 6 illustrates a schematic surface view of the electronic assembly shown in FIG. 5.

FIG. 7 is a plan view of the opposing surface of the substrate shown in FIG. 5.

FIG. 8 is a perspective view of the electronic assembly shown in FIG. 5 where the electronic assembly further includes a printed circuit board and a connector that connects the printed circuit board to the substrate.

### DETAILED DESCRIPTION OF THE INVENTION

In the following detailed description of the preferred embodiments, reference is made to the accompanying drawings which form a part hereof, and in which is shown by way of illustration specific embodiments in which the invention may be practiced. It is to be understood that other embodiments may be utilized and structural changes may be made without departing from the scope of the present invention.

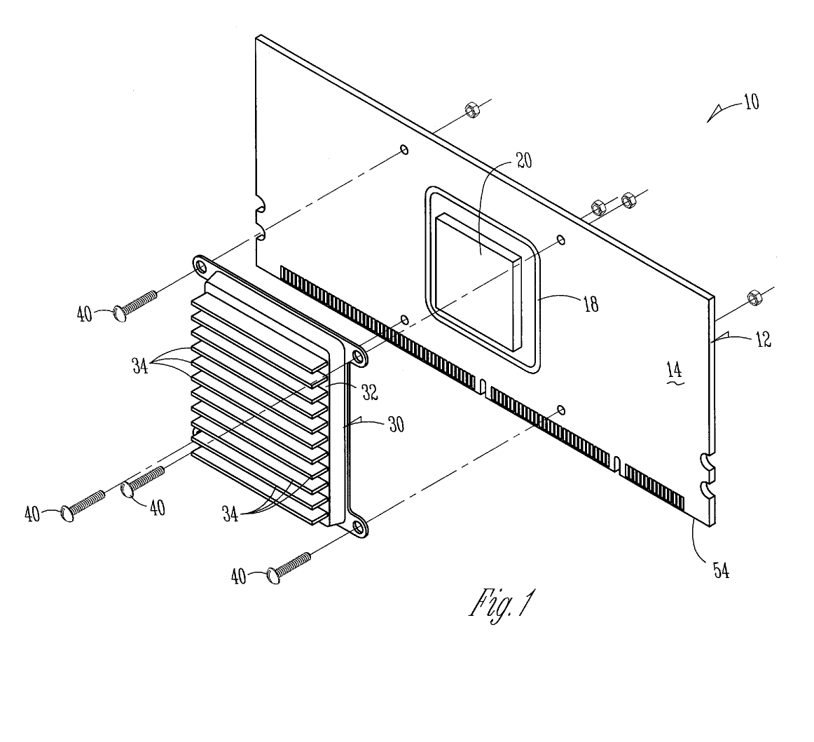

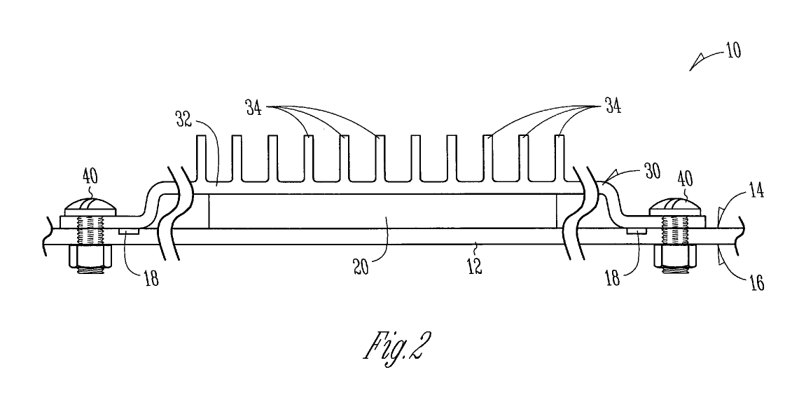

FIGS. 1-2 illustrate an example electronic assembly 10 of the present invention. The electronic assembly 10 includes a substrate 12 that has a first surface 14 and a second surface 16. The first surface 14 of the substrate 12 includes a grounding ring 18.

The electronic assembly 10 further includes an electronic component 20 that is mounted on the first surface 14 of the substrate 12 such that the grounding ring 18 at least partially surrounds the electronic component 20. As shown most clearly in FIG. 2, a heat sink 30 engages the electronic component 20 and the grounding ring 18 in order provide cooling and EMI shielding to the electronic component 20.

In the example embodiment that is illustrated in FIGS. 1 and 2, the grounding ring 18 surrounds the entire electronic component 20 and the heat sink 30 engages the entire grounding ring 18, although in some embodiments the grounding ring 18 may partially surround the electronic component 20 and the heat sink 30 may engage just a portion of the grounding ring 18. It should be noted that the grounding ring 18 may be placed on the first surface 14 of the substrate as part of the manufacturing process that is associated with the substrate 12, or added just before the heat sink 30 is attached to the grounding ring 18.

The electronic assembly 10 may further include fasteners 40 that extend through the heat sink 30 and the substrate 12 in order to secure the heat sink 30 to the substrate 12. It should be noted that any number and type of fasteners 40 may be used to secure the heat sink 30 to the substrate 12. In other embodiments, the heat sink 30 may be secured to the substrate 12 in some manner besurfaces using fasteners (e.g., by using an adhesive).

Although FIG. 2 shows that the heat sink 30 and the substrate 12 may fully enclose the first electronic component 20, it should be noted that in some embodiments the heat sink 30 and the substrate 12 may only partially enclose the first electronic component 20. The determination as to whether the heat sink 30 and the substrate 12 fully or partially enclose the electronic component 20 will depend in part on the (i) degree of shielding that is required for the electronic component 20; (ii) size of electronic component 20; (iii) arrangement of the electronic component 20 on the substrate 12; (iv) degree to which the grounding ring 18 surrounds the electronic component; and/or (v) manufacturing consurfacerations associated with electronic assembly 10.

It should be noted that the heat sink 30 may be a unitary structure or formed from more than one structure that is joined together to form heat sink 30. As an example, the fins 34 may be one or more sectional inserts that extend through opening(s) in the base 32 and are attached to the base 32.

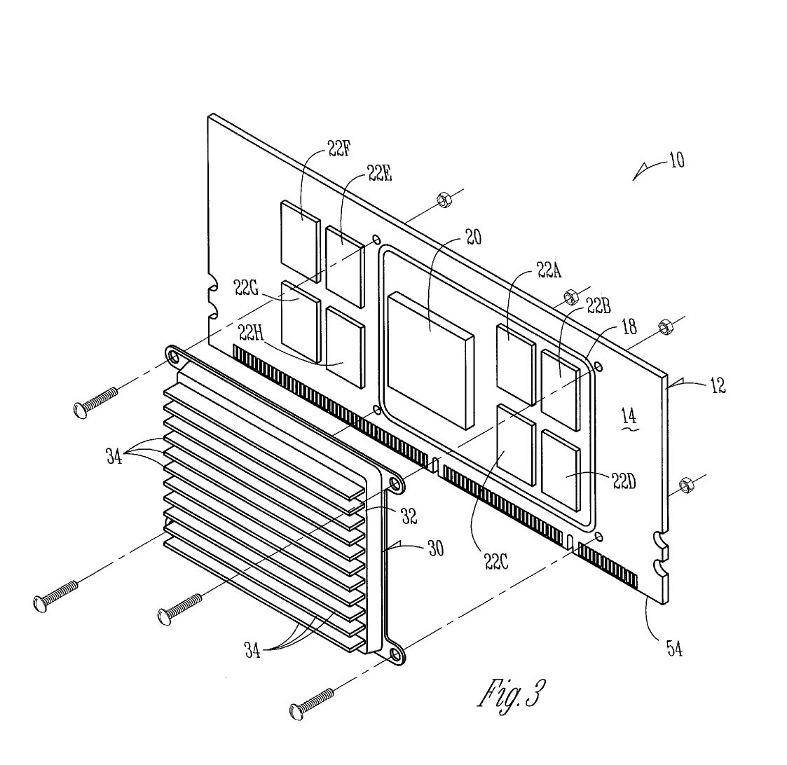

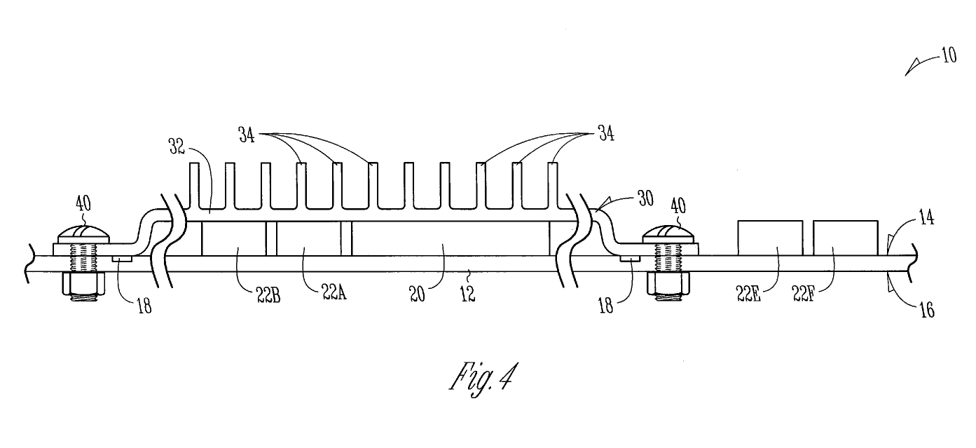

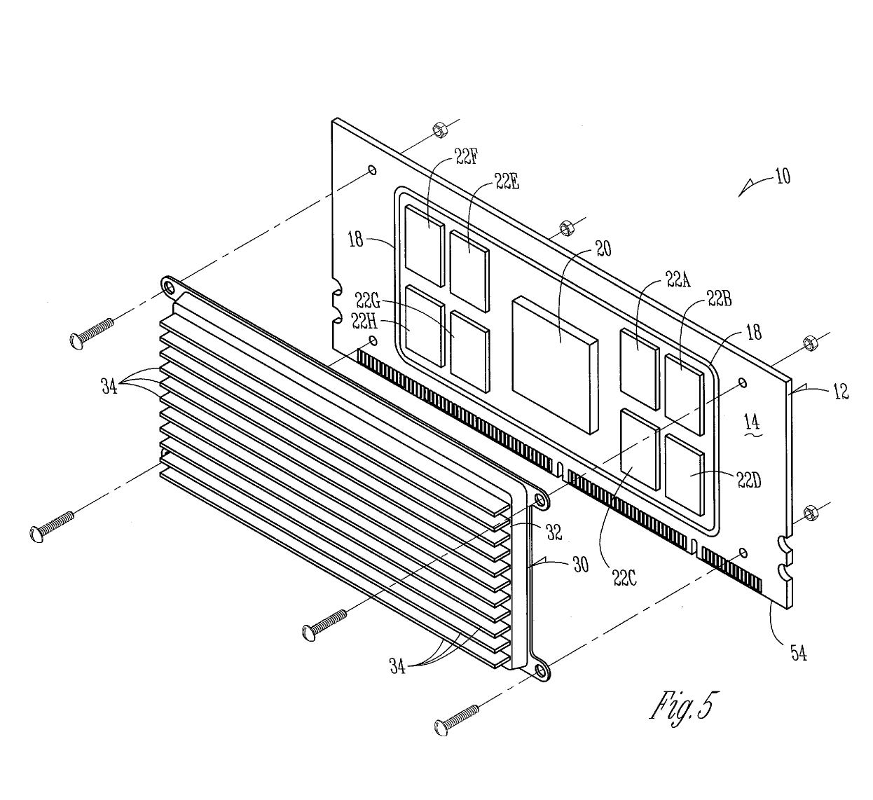

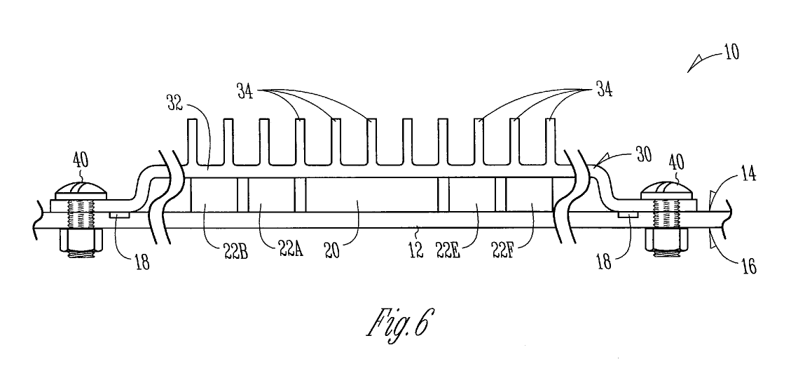

The electronic assembly 10 may further include additional electronic components 22A-H that are mounted on the first surface 14 of the substrate. In the example embodiment that is illustrated in FIGS. 3 and 4, the grounding ring 18 entirely (or partially) surrounds some of the electronic components 20, 22A-D on the first surface 14 of the substrate 12 while in the example embodiment that is illustrated in FIGS. 5 and 6, the grounding ring 18 entirely (or partially) surrounds all of the electronic components 20, 22A-H on the first surface 14 of the substrate 12. The heat sink 30 is adapted to engage each of the electronic components that are at least partially surrounded by the grounding ring 18.

Although FIGS. 3-6 shows that the heat sink 30 and the substrate 12 may fully enclose each of the electronic components that are surrounded by the grounding ring 18, it should be noted that in some embodiments the heat sink 30 and the substrate 12 may only partially enclose each of the electronic components that are surrounded by the grounding ring 18. As discussed above, the determination as to whether the heat sink 30 and the substrate 12 fully or partially enclose some the electronic components will depend in part on the (i) degree of shielding that is required for the electronic component 20; (ii) size of electronic component 20; (iii) arrangement of the electronic component 20 on the substrate 12; (iv) degree to which the grounding ring 18 surrounds the electronic component; and/or (v) manufacturing consurfacerations associated with electronic assembly 10.

In some embodiments, the electronic component 20 may be an application specific integrated circuit while one or more of the other electronic components 22A-H may be memory devices. In the example embodiments that are illustrated in FIGS. 3-6, four memory devices 22A-D are on one side of the application specific integrated circuit 20 and four more memory devices 22E-H are on an opposing side of the application specific integrated circuit 20.

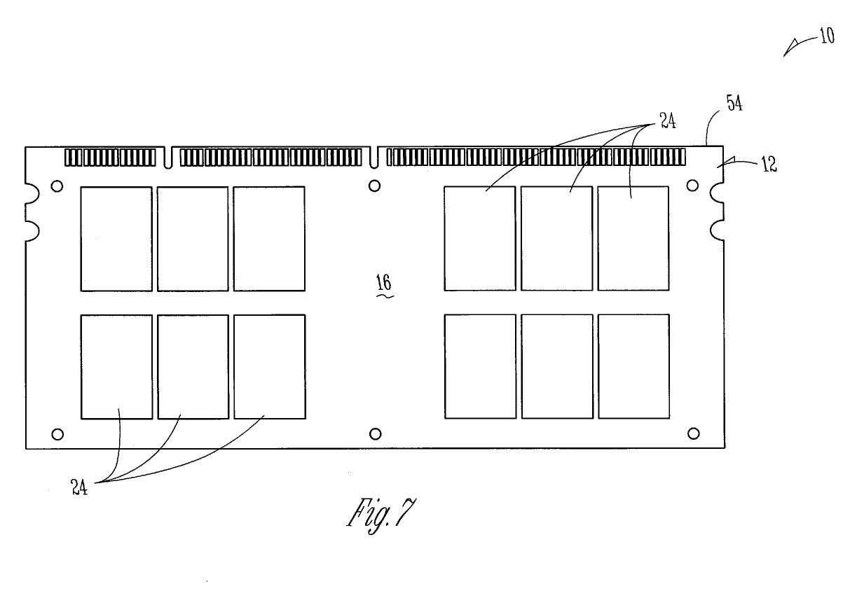

In some embodiments, the electronic assembly 10 may further include one or more additional electronic components 24 that are mounted on the second surface 16 of the substrate 12. FIG. 7 is a plan view of the opposing surface of the substrate shown in FIG. 5 which illustrates an example embodiment where additional memory devices 24 are mounted on the second surface 16 of the substrate 12. The particular number and arrangement of electronic components on the substrate 12 will depend in part on the desired operation and function of the electronic assembly 10 within an electronic device.

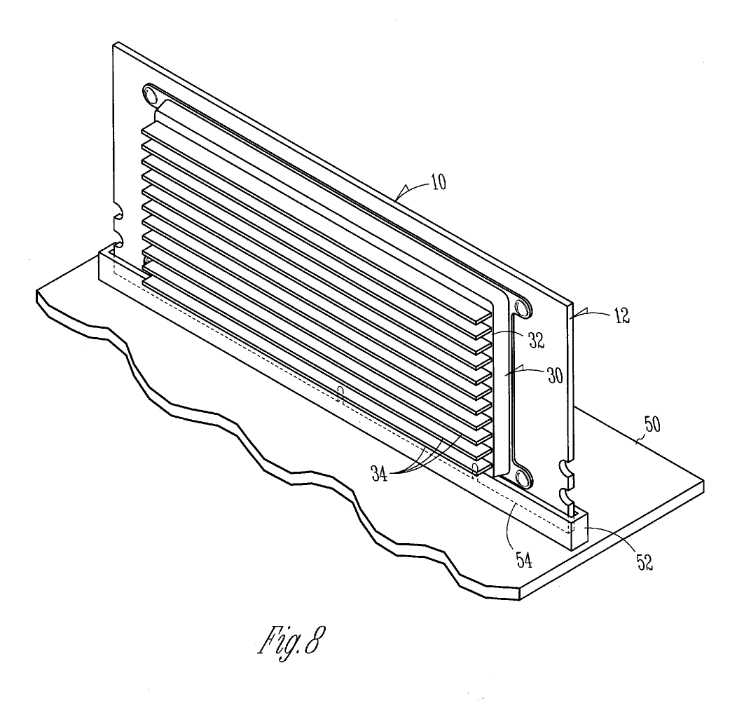

FIG. 8 illustrates an example embodiment of the electronic assembly 10 where the electronic assembly 10 further includes a printed circuit board 50 and a connector 52 that connects the printed circuit board 50 to the substrate 12. In the illustrated example embodiment, the substrate 12 includes a lateral edge 54 such that the connector 52 engages the lateral edge 54 of the substrate 12. It should be noted that although the substrate 12 is shown as being orthogonal to the printed circuit board 50, the substrate 12 may be at other angles relative to the printed circuit board 50.

Although specific embodiments have been illustrated and described herein, it will be appreciated by those of ordinary skill in the art that any arrangement which is calculated to achieve the same purpose may be substituted for the specific embodiment shown. This application is intended to cover any adaptations or variations of the present invention. Therefore, it is intended that this invention be limited only by the claims and the equivalents thereof.

1. An electronic assembly comprising:
a substrate that includes a first surface and a second surface, the first surface of the substrate including a grounding ring;
an electronic component mounted on the first surface of the substrate such that the grounding ring at least partially surrounds the electronic component;
a heat sink that engages the electronic component and the grounding ring in order provide cooling and EMI shielding to the electronic component;
a printed circuit board; and
a connector that connects the printed circuit board to the substrate, wherein the substrate is orthogonal to the printed circuit board and the substrate includes a lateral edge such that the connector engages the lateral edge of the substrate.

2. The electronic assembly of claim 1, wherein the grounding ring surrounds the entire electronic component.

3. The electronic assembly of claim 1, wherein the heat sink engages the entire grounding ring.

4. The electronic assembly of claim 1, wherein the heat sink is mounted directly to the substrate.

5. The electronic assembly of claim 1, wherein the heat sink is mounted directly to the grounding ring.

6. The electronic assembly of claim 1, further comprising fasteners that extend through the heat sink and the substrate in order to secure the heat sink to the substrate.

7. The electronic assembly of claim 1, wherein the heat sink and the substrate enclose the electronic component.

8. The electronic assembly of claim 1, further comprising additional electronic components mounted on the first surface of the substrate, and wherein the grounding ring at least partially surrounds a plurality of the electronic components on the first surface of the substrate and the heat sink engages each of the electronic components in the plurality of the electronic components.

9. The electronic assembly of claim 8, wherein the grounding ring entirely surrounds all of the electronic components in the plurality of the electronic components on the first surface of the substrate.

10. The electronic assembly of claim 9, wherein the heat sink engages the entire grounding ring.

11. The electronic assembly of claim 8, wherein the heat sink and the substrate enclose all of the electronic components in the plurality of the electronic components on the first surface of the substrate.

12. The electronic assembly of claim 8, wherein one of electronic components is an application specific integrated circuit and another of the electronic components is a memory device.

13. The electronic assembly of claim 12, wherein some of the other electronic components are memory devices.

14. The electronic assembly of claim 13, wherein at least two memory devices are on one side of the application specific integrated circuit and at least two more memory devices are on an opposing side of the application specific integrated circuit.

15-17. (canceled)

18. The electronic assembly of claim 1, further comprising at least one additional electronic component mounted on the second surface of the substrate.

19. The electronic assembly of claim 18, wherein at least some of the additional electronic components that are mounted on the second surface of the substrate are memory devices.
